(19) United States
(12) Patent Application Publication
(10) Pub. No.: US 2026/0229956 A1
(43) Pub. Date: Aug. 6, 2026

(54) ELECTROMECHANICAL DEVICE

(71) Applicant: HASAKI RESEARCH & TECHNOLOGY CENTRE PTY LTD, Brighton, Victoria (AU)

(72) Inventors: Andrew ROYALE, Brighton, Victoria (AU); Keiko Araki, Brighton, Victoria (AU)

(21) Appl. No.: 19/152,241

(22) PCT Filed: Jan. 19, 2024
(86) PCT No.: PCT/AU2024/050031

§ 371 Date: Jul. 30, 2025

(30) Foreign Application Priority Data
Feb. 3, 2023 (AU) 2023900259

(51) Int. Cl. H02K 7/18; H02K 3/04; H02K 7/00; H02K 9/19

(52) U.S. Cl. CPC H02K 7/18; H02K 3/04; H02K 7/006; H02K 9/19

(57) ABSTRACT

An electromechanical device having a stator, a rotor and one or more thermoelectric generator (TEG) portions positioned to accept heat from at least one of the stator and the rotor.

### FIELD OF THE INVENTION

The invention relates to electromechanical devices such as electric motors and generators.

### BACKGROUND

An electric motor is a device that consumes electrical power and produces shaft power. An electric generator is a device that consumes shaft power and produces electrical power. Certain apparatus are capable of being operated as either an electric motor or a generator.

Electric motors have long been used in vehicles for powering ancillary devices such as cooling fans and the use of electric motors to move vehicles is increasingly popular. Vehicles comprising an electric motor to supplement an internal combustion engine are known as “hybrid vehicles” whereas vehicles that rely solely upon an electric motor for motive force are referred to as “electric vehicles”.

Some vehicles employ a generator to consume shaft power from the road-engaging wheels of the vehicle and thereby slow the vehicle (or regulate the speed of the vehicle on a decline). This is referred to as “regenerative braking”.

Typical electromechanical devices are not 100% efficient. Some power is lost in the conversion between electrical power and shaft power. The present inventors have recognised that it would be useful to recapture at least some of this lost power.

With the foregoing in mind, the present invention aims to provide improvements, or at least alternatives, in and for electromechanical devices.

It is not admitted that any of the information in this patent specification is common general knowledge, or that the person skilled in the art could be reasonably expected to ascertain or understand it, regard it as relevant or combine it in any way before the priority date.

### SUMMARY

The present inventors have recognised that existing electromechanical devices lose energy to heat, this heat can be recaptured using one or more thermoelectric generators (TEGs) and efficiencies can be realised by positioning the TEG portions to accept heat from specific portions of the electromechanical device.

A TEG is a solid-state device that generates electrical power when exposed to a temperature difference. Typical TEGs are thin plate-like or web-like devices having two major sides respectively corresponding to a heat-accepting side and a heat-rejecting side.

Generally speaking, there are three different types of TEG units. A first type comprises ceramic substrate rigid TEG units that are constructed electrically in series between each of the P and N semiconductor pairings and thermally in parallel.

A second type is of a flexible nature that is constructed as the rigid type of TEG in series, with flexible electrodes and substrates, that allow it to bend in the one direction only (neglecting a small degree of “TEG unit stack up flex” in other directions, which flex is typically less than 20 degrees). The present inventors recognise that the uniaxially flexible TEG units are unable to bend in a second direction because they are constructed in series and thermally in parallel, which results in a lack of mechanical strength in the second direction and breakage of the flexible TEG unit through the flexible substrate and electrodes.

A third type is biaxially flexible. The bend rotation in the second direction is greater than >300 degrees. These biaxal TEG units are each constructed in clusters of P and N semiconductor pairings. For example, Group A, of P and N semiconductor could bend in one axis and Group B, of P and N semiconductors in another axis direction, working independently within the one biaxal TEG unit. Group A and Group B are not connected together in their power generation process and separately integrate supply electrical power.

One aspect of the invention provides an electromechanical device comprising
a stator;
a rotor; and
one or more TEG portions positioned to accept heat from at least one of the stator and the rotor.

Preferably, a casing encases the stator, the rotor and the one or more the TEG portions. Most preferably, the electromechanical device comprises a cooling path, within the casing, to carry cooling air over at least one of the one or more TEG portions.

Optionally, the stator comprises windings and the one or more TEG portions comprise a winding-powered TEG portion positioned on a portion of the windings. The winding-powered TEG portion may be wrapped about the portion of the windings. The winding-powered TEG portion is preferably a flexible TEG portion, or more preferably a biaxially flexible TEG portion. Optionally, a body of glue is bonded to each of the winding-powered TEG portion and the portion of the windings.

Optionally, the stator comprises a lamination stack and the one or more TEG portions comprise a lamination-powered TEG portion positioned on a portion of the lamination stack. The lamination-powered TEG portion may be wrapped about the portion of the lamination stack. The lamination-powered TEG portion is preferably flexible. Preferably, a body of glue is bonded to the lamination-powered TEG portion and to laminations of the lamination stack.

Optionally, the one or more TEG portions comprise a rotor-powered TEG portion positioned on a portion of the rotor, preferably on an interior of the rotor. Preferably, the rotor-powered TEG portion is flexible, e.g. biaxially flexible. A body of glue may be bonded to each of the rotor-powered TEG portion and the rotor.

Preferably, at least one of the one or more of the TEG portions is flexible, e.g. biaxially flexible.

The electromechanical device may be an electric motor for moving, and/or a generator for regeneratively braking, a vehicle.

Another aspect of the invention provides an electromechanical device comprising
a stator;
a rotor; and
one or more TEG portions positioned to accept heat from at least one of the stator and the rotor;
wherein the stator comprises
   a lamination stack; and
   head windings each comprising a ring about an end of the lamination stack; and
the one or more TEG portions comprise one or more winding-powered TEG portions; and
the one or more winding-powered TEG portions are biaxially flexible.

Another aspect of the invention provides an electromechanical device comprising
a stator;
a rotor; and
one or more TEG portions positioned to accept heat from at least one of the stator and the rotor;
wherein the stator comprises
   a lamination stack; and
   head windings each comprising a respective ring about a respective end of the lamination stack; and
the one or more TEG portions comprise one or more winding-powered TEG portions covering at least most of the head windings.

Preferably, the one or more TEG portions cover at least 90% of head windings.

Optionally, at least one respective heading winding of the head windings has a respective inner retainer running around at least most of an inside of the respective head winding and outwardly urging TEG portions against the respective heading winding.

In an embodiment, the respective inner retainer is resiliently deformed inwards to outwardly urge TEG portions against the respective heading winding.

Optionally, at least one respective heading winding of the head windings has a respective outer retainer running around at least most of an outside of the respective head winding and inwardly urging TEG portions against the respective heading winding.

In an embodiment, the respective outer retainer is resiliently deformed outwards to inwardly urge TEG portions against the respective heading winding.

The electromechanical device may comprise flow paths that convey fluid to cool the one or more winding-powered TEG portions. Preferably, the flow paths cool the head windings in parallel to each other.

Another aspect of the invention provides an electromechanical device comprising
a stator;
a rotor;
one or more TEG portions positioned to accept heat from at least one of the stator and the rotor; and
flow paths that convey fluid to cool the one or more winding-powered TEG portions;
wherein the stator comprises
   a lamination stack; and
   head windings each comprising a ring about an end of the lamination stack;
the one or more TEG portions comprise one or more winding-powered TEG portions; and
the flow paths cool the head windings in parallel to each other.

Another aspect of the invention provides an electromechanical device comprising
a stator comprising a lamination stack;
a rotor;
one or more TEG portions positioned to accept heat from at least one of the stator and the rotor;
flow paths that convey fluid to cool the one or more TEG portions; and
a cooling system that supplies cooled fluid to the flow paths.

The cooling system may comprise a heat pump. Optionally, the cooling system comprises an air-conditioner that cools an interior of a vehicle.

Another aspect of the invention provides an electromechanical device comprising
a stator;
a rotor; and
one or more TEG portions positioned to accept heat from at least one of the stator and the rotor;
wherein the stator comprises a lamination stack; and
the one or more TEG portions comprise one or more lamination-powered TEG portions covering at least most of an exterior of the lamination stack.

Preferably, the one or more lamination-powered TEG portions cover at least 90% of an exterior of the lamination stack.

Another aspect of the invention provides the vehicle. The vehicle may be an electric vehicle. Alternatively, it may be a hybrid vehicle. Preferably, it is a road vehicle.

### BRIEF DESCRIPTION OF DRAWINGS

FIG. 1a is a perspective view of a stator carrying a TEG;

FIG. 1b is a cut-away view showing a quadrant of a stator carrying a TEG;

FIG. 2 is a half-section view of another stator carrying a TEG;

FIG. 3 is a perspective of another stator carrying a TEG;

FIGS. 4a, 4b and 4c schematically illustrate a flexible TEG;

FIGS. 5a and 5b illustrate two TEG pieces mutually connected via a plug and socket;

FIGS. 6a, 6b and 6c illustrate two TEG pieces mutually connected by a flexible connection;

FIGS. 7a and 7b illustrate two TEG pieces mutually connected by a flexibly mounted plug and socket;

FIG. 8a illustrates a TEG;

FIG. 8b is a cut-away view showing a quadrant of a rotor fitted with the TEG of FIG. 8a;

FIG. 8c is a cut-away view showing the rotor and TEG of FIG. 8b in combination with a shaft;

FIG. 9 is a cut-away view showing a quadrant of an electric motor;

FIG. 10a is a cut-away view showing a quadrant of a stator, TEG, casing combination;

FIG. 10b is an exploded view of the combination of FIG. 10a;

FIG. 11 is a schematic plan view of a hybrid vehicle;

FIG. 12a illustrates a one-piece TEG laid flat;

FIG. 12b illustrates a one-piece TEG formed to fit over a head winding;

FIG. 12c is a perspective view of the TEG piece of FIG. 12b held in place by restraints;

FIG. 13a is a cut-away view of a half-toroidal TEG piece fitted to a head winding;

FIG. 13b illustrates a portion of the TEG piece of FIG. 13a in combination with a restraint;

FIG. 13c is a perspective view of a portion of an alternative half-toroidal TEG piece;

FIG. 14a is a perspective view of an alternative head-winding-powered TEG piece;

FIG. 14b is a plan view of the TEG piece of FIG. 14a in its closed configuration;

FIG. 15 is a perspective cut-away view of a rotor-powered TEG piece;

FIG. 16a is an exploded view of a motor/generator unit;

FIG. 16b is a cross-section view of the motor/generator unit of FIG. 16a; and

FIG. 17 is a half-section view of an alternative motor/generator unit.

### DESCRIPTION OF EMBODIMENTS

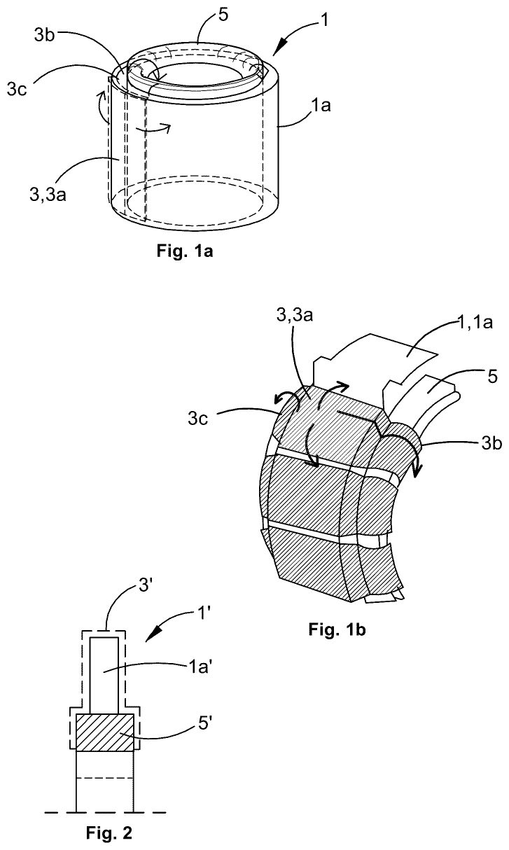

FIG. 1 shows a stator 1 equipped with a TEG 3. The stator 1 comprises a lamination stack 1a in the form of a short, approximately cylindrical tube. The stack 1a is made of individual laminations each being in the vicinity of, say, 0.7 mm thick and having a generally annular form. Each lamination typically comprises a main body of steel and a surface coating by which the steel is electrically insulated from the adjacent lamination.

Typically, the interior of each lamination is punctuated by a circular array of cut-outs. The cut-outs sit in register with respect to each other so these cut-outs define lengthwise channels. These channels inside the lamination stack carry windings.

Typical windings are formed of enamel coated copper and wound repetitively so that a strand follows an internal channel and at the end of the channel is turned to return back along another internal channel. Often the channels within the lamination stack are lined with plastic to protect the windings therein.

The winding portions exposed at each end of the stack together form a ring about the end of the lamination stack that often has an approximately toroidal form facing axially outwards. This end portion is referred to as a “head winding”.

FIG. 2 illustrates an alternate form of stator 1′ comprising a lamination stack 1a, and exposed winding portion 5′ and surrounded by a TEG 3′. Whereas the stator 1 is a tube having a length similar to its width, the stator 1′ is a shorter disc-like form.

Preferably, the TEG 3 is part of a set of TEG portions covering at least most of an exterior of a lamination stack 1a, and/or covering at least most of the windings, outboard of the rotor (or inboard in the context of an external rotor motor) and would otherwise be exposed. Preferably, mechanically separate TEG portions are spaced around the stator 1.

This example of the lamination stack 1a comprises a cylindrical exterior. The TEG 3 is flexible and comprises a portion 3a conforming to the cylindrical exterior and a head winding portion 3b that adopts an about-toroidal form to wrap around the head winding. The TEG 3 comprises an intermediate portion 3c mutually connecting portions 3a, 3b. Preferably, the TEG 3 comprises a uniform arrangement of P and N semiconductors and two electrodes flexible, to bend biaxially, and attached to a flexible substrate. The flexible substrate might be made from a perovskite, polymer plastic or silicon-based material. Optionally, elements of graphene and/or graphite are embedded into the substrate to improve the thermal conductivity into the TEG unit. Flexible TEGs are preferred because they conform to the curvatures of existing motor designs without the need to modify the lamination profile or the need for shaped mounting features to occupy the space between a cylindrical lamination stack and a planar TEG surface.

The inventors' experiments have shown that directly placing TEGs on the lamination stack 1a is more efficient. Optionally, the TEG is fitted with the aid of thermally conductive glue without other components intervening whereby a single body of glue is adhered to each of the lamination stack 1a and the TEG portion 3a. The glue fixes the TEGs to the lamination stack and conforms to the surfaces of the lamination stack and the TEG portions for effective heat transfer. Other thermally conductive, conformable materials, such as thermal paste or graphite, might be used, e.g. in combination with other modes of fixation.

The TEG 3 takes the form of a simple strip of material that is “biaxially flexible”, that is able to flex about two axes to conform to a toroidal or spherical surface, and is thereby able to closely conform to the shape of the head winding.

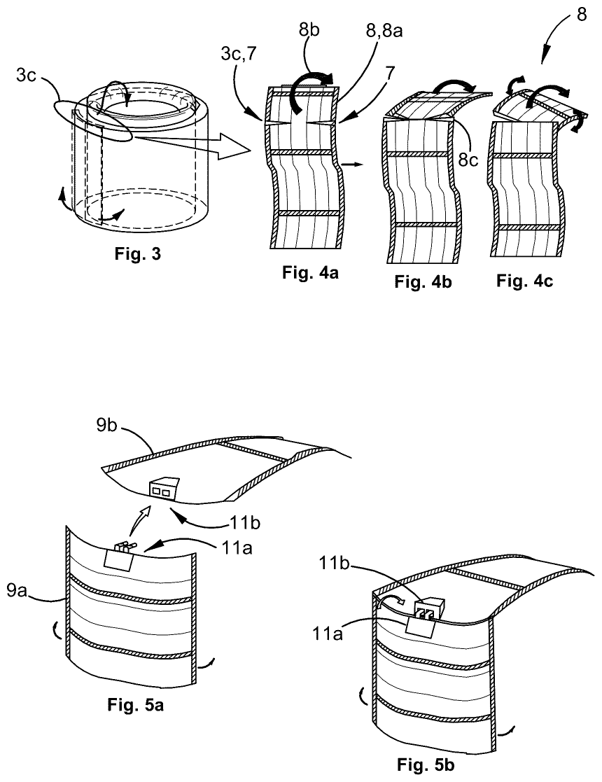

In this example, there may be some gathering of material in the transition region 3c. Accordingly, in another variant of the system illustrated in FIGS. 3 to 4C the intermediate portion 3c has a pair of cuts 7 extending inwardly from each edge to enable the TEG portions to conform more closely to the stack 1a and the head portion. As suggested in FIGS. 4b and 4c, the cuts 7 leave the portions 3a, 3b mutually connected by a narrow neck of flexible material whereby the portions 3a, 3b can freely twist and move relative to each other.

Thin substrates are preferred. Optionally, the substrate may be reinforced with reinforcement 8, such as edge reinforcements 8a running along each of the two long edges of the strip, cross-wise reinforcements 8b running across the width of the strip at locations spaced along the strip to divide the strip into approximately square sectors, and potentially also edge reinforcements 8c along the edges of the slots 7.

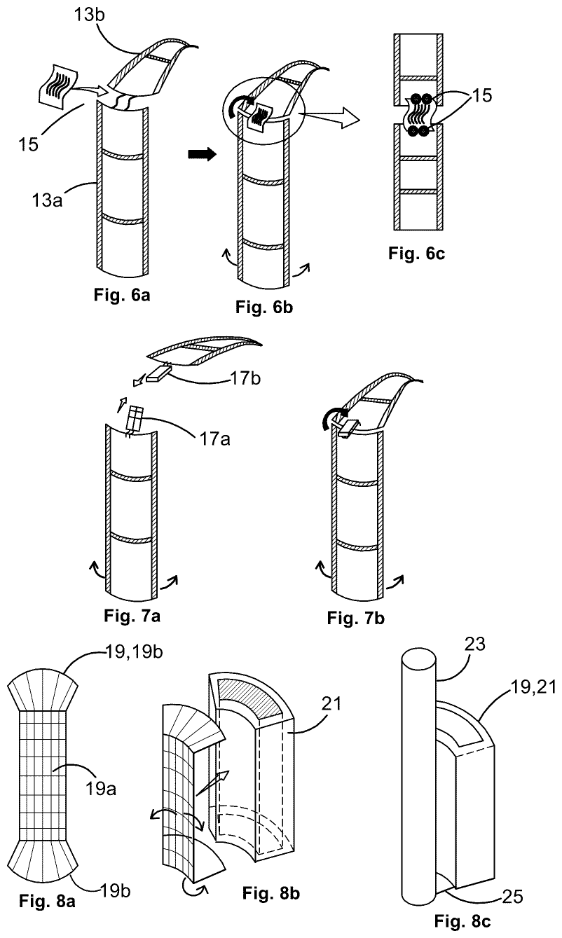

FIGS. 5a to 7b illustrate alternate options comprising separable TEG portions, relatable to TEG portions 3a, 3b and mutually connected. Mutually connecting to distinctive TEG portions enables different types of TEG materials to be brought together. By way of example, it may be more cost-efficient to make the lamination-powered TEG portion 9a out of material that is flexible about only a single axis and to connect that portion to a winding-powered portion 9b that is biaxially flexible. FIGS. 5a, 5b illustrate a plug 11a mounted directly on respective TEG portions. The plug 11a and socket 11b are examples of connectors mutually co-operable to electrically connect TEG portions to each other. FIGS. 6a to 7b illustrate other connection arrangements. FIGS. 6a to 6c illustrate an example in which a lamination stack-powered TEG portion 13a is connected to a winding-powered portion 13b by a flexible connection arrangement 15. The flexible connection arrangement could take any convenient form, e.g. it may comprise flexible conductors soldered to terminals of the TEG portions 13a, 13b.

FIGS. 7a and 7b illustrate a variant in which the TEG portions are mutually connectable via a flexibly mounted plug 17a and a socket 17b flexibly mounted and co-operable with the plug 17a.

FIGS. 8a to 8c illustrate a rotor-powered TEG portion 19 comprising a central portion 19a mountable to cover a cylindrical interior of a rotor 21. End portions 19b are shaped to wrap over the ends of the rotor 21. In this example, the combination 19, 21 is dimensioned to define an air gap 25 about a shaft 21.

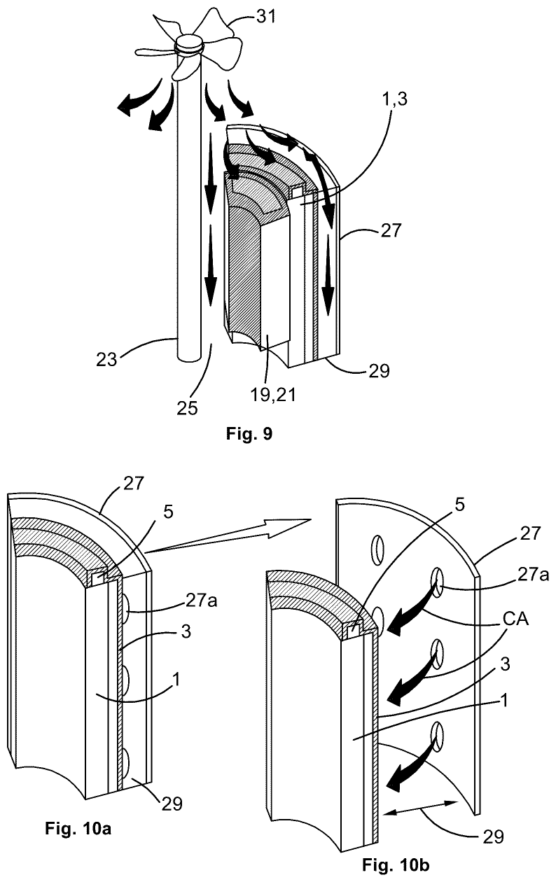

FIG. 9 illustrates a quadrant of an electric motor comprising stator/TEG combination 1, 3 surrounding rotor/TEG combination 19, 20 and shaft 23. This assembly of parts is in turn encased in a casing 27 to define an air gap 29. In this example, a cooling fan 31 is fixed to rotate with the shaft 23 and drive cooling air along air gaps 25, 29 so as to flow over the TEG 19, 3. The casing is preferably an aluminium casing.

In this way, the TEGs are positioned to accept heat directly from the stator and rotor, both of which may well be upwards of 100° C., e.g. upwards of 150° C., and to reject heat to the cooling air which may well be ambient or air-conditioned air.

Exposing the TEG portions directly to the hot components of the motor improves the performance of the TEGs and provides for a more controlled environment. In particular, the cooling air flow can be more carefully controlled and the casing 27 serves to protect the TEGs from damage.

Preferred variants of the casing guard against objects greater than 1 mm in diameter reaching a conductor. It is also preferred that the casing guards the electrical components from splashing water, e.g. it is preferred that the casing has an IP rating of at least IP44. Most preferably, the casing is at least dust-protected (IP5X) or more preferably dust-tight (IP6X). A higher degree of water protection such as protection against water jets (IPX5), or more preferably at least powerful water jets (IPX6), is preferred. In the context of ventilated systems, these higher ratings may be achieved with the aid of filters and/or water traps.

FIG. 9 illustrates a motor comprising an air gap 29 with an annular cross-section. The fan 31 establishes a pressure gradient to cause air to flow axially through the air gap 29. Another variant may comprise a second fan on the other end of the shaft 23 to draw air through the air gaps. Fanless variants are also possible, e.g. the motor may be connectable to a cooling system that delivers a flow of cooling air to the motor.

FIGS. 10a, 10b illustrate another variant in which the casing 27 is penetrated by cooling holes and a pressure gradient is established whereby cooling air CA travels radially inwards through these cooling holes and impinges upon the TEG portion 3 mounted on the stator 1.

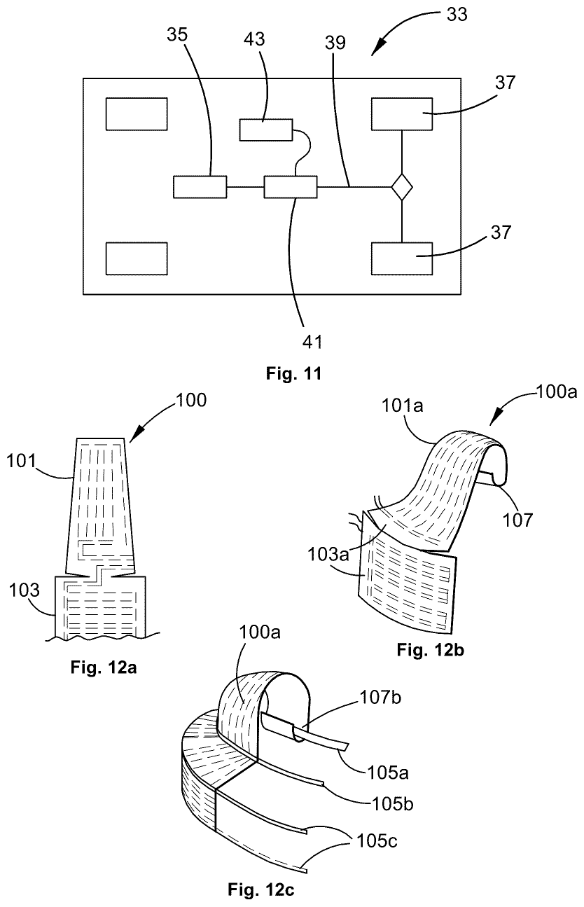

FIG. 11 schematically illustrates a hybrid vehicle 33 comprising a combustion engine 35, drive wheels 37, a mechanical transmission 39 for transmitting shaft power from the combustion engine 35 to the drive wheels 37, an electromechanical unit (EMU) 41 along the transmission 39, and a battery 43 electrically connected to the EMU 41. The EMU is equipped with TEGs to recover energy.

The transmission 39 is capable of transmitting shaft power in either direction between the EMU 41 and motor 35 on the one hand, and the drive wheels 37 on the other.

The EMU has both a motor mode and a generator mode. In some modes of operation (e.g. when the vehicle is in slow-moving traffic), the EMU 41 may be the sole source of shaft power to the drive wheels. At other times, the engine 35 and the EMU 41 may simultaneously supply shaft power. Other times, the EMU 41 can be operated to take power from the drive wheels 37 for regenerative braking and/or to take power from the combustion engine 35.

Some variants of the electromechanical devices disclosed herein may be usefully applied in other contexts, e.g. in the context of vehicles other than road vehicles and in contexts unrelated to vehicles. By way of example, some generator variants may be usefully employed to improve the efficiency of wind turbines. Other generator variants may be driven by other sources of shaft power, e.g. driven by an internal combustion engine. Potentially, such a generator variant may appear in the context of a vehicle and separately from any regenerative braking. By way of example, such a combustion engine/generator combination may be added to, to extend the range of, an electric vehicle.

FIG. 12a illustrates an end of an alternative TEG piece 100 comprising a biaxially flexible portion 101 mechanically and electrically connected to a uniaxially flexible portion 103. The biaxially flexible portion 101 fits over a head winding. The portions 101, 103 have mutually distinct groups of P and N semiconductors that operate independently to generate electrical power. Optionally, the piece 100 is double-ended, comprising a respective biaxially flexible portion at each end to wrap over each of the head windings.

FIG. 12b illustrates an alternative TEG piece 100a comprising biaxially flexible portion 101a and uniaxially flexible portion 103a mechanically connected to, but electrically isolated from, each other.

Whilst thermally conductive glue is one option for attaching the TEGs, the present inventors have recognised that such glues can limit serviceability. By way of example, a TEG glued to a head winding would make it difficult to replace the TEG without rewinding the motor.

FIG. 12c illustrates preferred restraints 105a, 105b, 105c by which a plurality of TEG pieces 101a, arrayed around the motor, are held in place.

The TEG 100a comprises an inner hook 107 that sits radially inside the head winding. The hook 107 opens axially, is within the TEG portion 101a, and carries the retainer 105a.

The retainer 105a is a resilient piece akin to an internal circlip. It turns through almost 360 degrees around the motor and is resiliently deformed inwards to axially pass the head winding. When released, the resilient element 105a springs outwardly to urge the winding-powered portion 101a against the head winding. Restraint 105b is another resilient element and is akin to an external circlip. It is expanded, placed and then released to spring inwardly and thus urge the winding-powered portion 101a against the head winding. Restraints 105c are relatively larger restraints akin to the restraint 105b and urge lamination-powered portions of the TEG 103a radially inwards against the cylindrical exterior of the lamination stack.

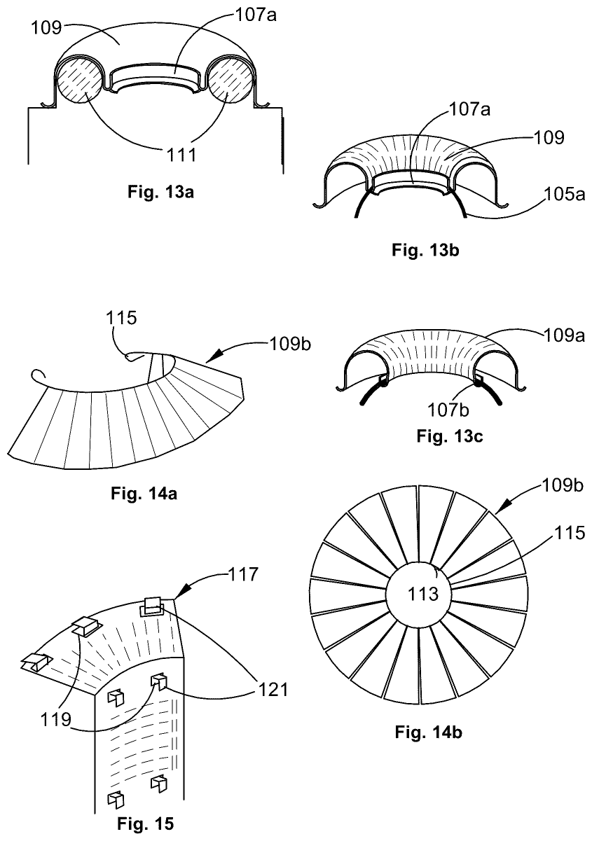

FIG. 13a illustrates an alternative winding-powered TEG piece 109. Instead of a set of winding-powered pieces arrayed about the motor as in FIG. 12c, the winding-powered piece 109 has a half about-toroidal form to fit over the head winding 111 that is, the piece 109 is a ring having a radial profile open to receive the head winding. The radial profile of the piece 109 is a channel profile that is about U-Shaped.

The winding-powered piece 109 (and the corresponding set of portions 100a) entirely covers the head winding 111 to better capture heat from the head winding. The TEG piece 109 comprises a radial inner hook 107a that turns radially inwards to open axially away from the stator laminations and be accessible from outside of the head-winding-powered portions. This orientation enables the retainer 105 to be placed after the winding-powered portion 109 has been placed on the head winding 111.

FIG. 13c illustrates an alternative half-toroidal winding-powered TEG piece 109a comprising a hook 107b that opens inside the radial profile of the winding-powered TEG portion as per the hook 107 of FIG. 12c.

FIGS. 14a, 14b illustrate another TEG-powered winding portion 109b comprising an array of biaxially flexible TEG portions about a central opening 113. The TEG piece 109b comprises a resilient element 115 attached to the inner peripheries of the TEG portions. The resilient element 115 incorporates mutually-complementary releasable fastening features, in this case a hook and a loop, co-operable to hold the element 115 in a closed, contracted form as in FIG. 14b. The piece 109b can then be maneuvered to place the resilient element 115 inside a head winding and adjacent to the lamination stack. Once in this position, the hook-and-loop (or other releasable fastening arrangement) can be released to enable the element 115 to spring outwardly as per the retainer 105a.

These circlip-like resilient elements provide a convenient means for holding the TEG portions in place and promoting efficient heat transfer whilst maintaining serviceability. The circlip-like restraints are but one example of the concept. In another implementation, the restraint might take the form of a closed loop that is resiliently expanded (or contracted) and released to inwardly (or outwardly) urge a TEG portion against a heat source. By way of example, the restraint 105b might be replaced by a long tension spring, the ends of which are mutually connected.

In another implementation, the resilient elements 105a, 105b, 105c might be replaced by other means for radially urging. By way of example, the restraint 105b might be replaced by a restraint in the form of a band akin to a hose clamp and screw tightenable to hold the winding-powered TEG portion against the head winding.

Other releasable means of mounting the TEG portions are possible, e.g. springs, hooks, straps, clamps, rings, belts and/or tabs may be employed. Optionally, the TEG portions may comprise openings, such as reinforced openings, by which the TEG portions are tied in place. FIG. 15 illustrates a TEG portion 117 comprising openings 119 fitted to hooks 121 of a rotor to tie the portion 117 in place.

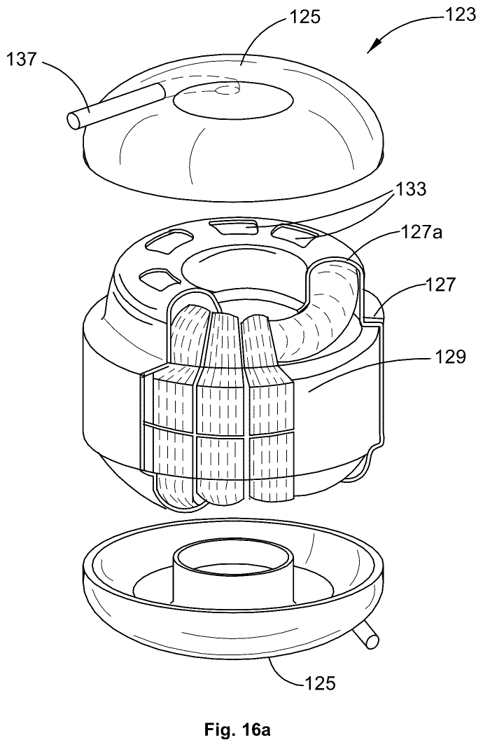

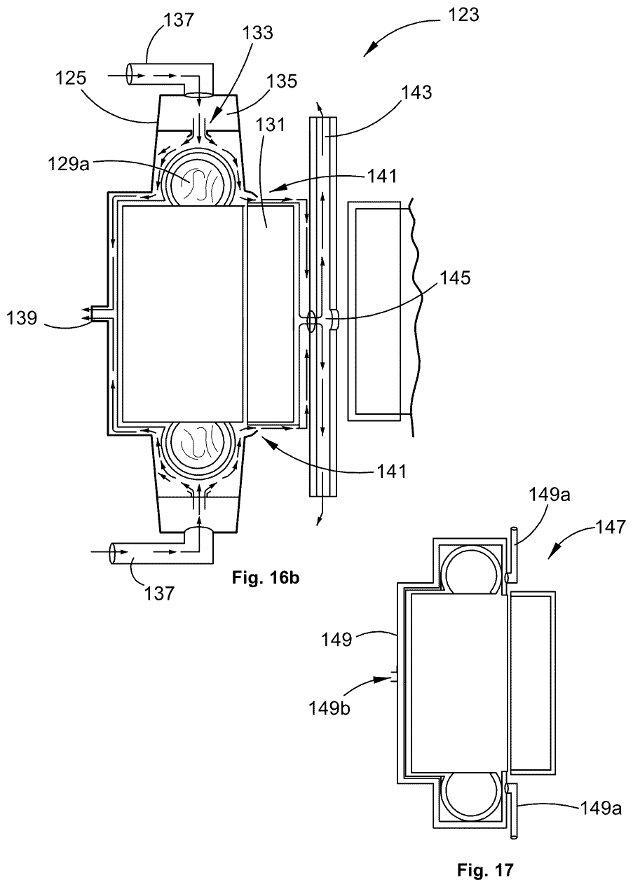

FIGS. 16a and 16b illustrate a motor/generator unit 123 incorporating cooling caps 125 and cooling case 127 embracing a stator/TEG combination 129.

The case 127 defines a narrow air gap through which a turbulent stream of air is moved to cool the TEGs. Optionally, coolants other than air, e.g. water, may be adopted.

The unit 123 further includes cooling arrangements by which the rotor/TEG combination 131 (FIG. 16b) is cooled.

Each cooling cap 125 comprises a ring, the radial profile of which is a channel profile, to receive an end portion 127a of the casing 127, that has a corresponding ring-like form. The radial profile of the end portion 127a is also channel-profiled to fit over the head winding of the combination 129.

The end portion 127a is penetrated by a set of openings 133. When assembled, the cap 125 and casing 127 together define an annular plenum 135. An inlet 13 supplies cooling air to the plenum 135 and the openings 133 distribute the air to the head winding 129a of the combination 129. The combination 127a, 125 thus constitutes a flow distributor for distributing cooling fluid to radially separate portions of the head winding in parallel for more uniform and efficient cooling of the head winding. Other flow-distributing plenums, and other flow distribution arrangements more generally, are possible.

Each end of the unit 123 has a similar flow distribution arrangement whereby each of the two ends, or more specifically each of the two head windings, are cooled in parallel. In this way, each of the head windings receives “fresh” cooling air that has not already been warmed by heat from the other head winding. This leads to more uniform and efficient cooling. Air exits the casing 127 via one or more outlets 139 opening radially outwards from the lamination stack of the combination 129.

In this example, air also exits radially inwards via annular outlets 141 in proximity to the ends of the lamination stack.

This example of the concept comprises a hollow shaft 143 running through the centre of the rotor. The exterior of the shaft is inwardly spaced from the TEG portions carried within the rotor to define an air gap. An inlet arrangement 145, in this case comprising a pair of opposed radial openings, connects the interior of the shaft 143 to the air gap about the shaft 143. Air is drawn from the shaft, in this case via each end of the shaft 143, whereby air emerging inwardly from the outlets 141 flows radially inwards, over the ends of the rotor, and then axially inwards toward the inlet arrangement 145 through the air gap and to cool the internal rotor-powered TEGs.

In a preferred implementation, the housing 125, 127 is extended radially inwards to sealingly engage the shaft 143 and define the axially-outer bounds of the flow paths along which coolant coming off the head windings flows radially inwards en route to the air gap around shaft 143. This enables the housing 125, 127 to be pressurised. Testing suggests that pressurisation leads to improved cooling and is preferred regardless of the configuration of the cooling housing.

The illustrated cooling system splits the heat laden coolant between the outlets 139, about the periphery of the unit 123, and the outlets at the ends of the shaft 143. In preferred implementations, a fraction of the head-laden coolant (e.g. the coolant carried by the shaft 143) is conveyed to cool other components (e.g. other components in the drive train of a vehicle).

In this preferred example, most (e.g. at least 90%) of an exterior of the stator-rotor combination is covered in TEG portions. Likewise, in the illustrated implementation, most (e.g. at least 90%) of an exterior of the stator/rotor/TEG combination is bathed in cooling air. Bathing the exterior in moving, cooling air (as opposed to exposing the TEG portions to hot, stagnant air) improves efficiency.

In some implementations, the coolant might be ambient air. In other contexts, it may be advantageous to cool the air. This may entail a heat pump, most preferably the heat pump of an air-conditioner already in place to cool a space for a user, such as to cool the cabin of a vehicle. By way of example, the inlets 137 might be supplied with fluid drawn from the vehicle's air-conditioner.

Other cooling fluids are possible. FIG. 17 schematically illustrates a half-section view of a water-jacketed stator/rotor combination 147 comprising a water jacket 149 equipped with a pair of inlets 149a and a set of outlets 149b arrayed about the exterior of the unit 147. In the context of a hydroelectric power station, e.g. a pumped hydroelectric power station, the water might make a single pass through the jacket 149. Closed loop systems may be convenient in other contexts, e.g. the water (or other coolant) might emerge from the outlets 149b and be cooled by a heat pump before being returned to the inlets 149a.

The term “comprises” and its grammatical variants has a meaning that is determined by the context in which it appears. Accordingly, the term should not be interpreted exhaustively unless the context dictates so. Likewise, the article “a” or “an” preceding an element does not exclude the presence of a plurality of such elements unless the context dictates so.

The invention is not limited to the examples disclosed herein. Rather, the invention is defined by the claims.

1-26. (canceled)

27. An electromechanical device comprising
a stator;
a rotor; and
one or more thermoelectric generator (TEG) portions positioned to accept heat from at least one of the stator and the rotor;
wherein the stator comprises a lamination stack; and
at least one of:
(a) the stator comprises head windings each comprising a respective ring about a respective end of the lamination stack, the one or more TEG portions comprise one or more winding-powered TEG portions covering at least most of the head windings, and the at least one respective heading winding of the head windings has a respective inner retainer running around at least most of an inside of the respective head winding and outwardly urging TEG portions against the respective heading winding;
(b) the stator comprises head windings each comprising a respective ring about a respective end of the lamination stack, the one or more TEG portions comprise the one or more winding-powered TEG portions covering at least most of the head windings, and the at least one respective heading winding of the head windings has a respective outer retainer running around at least most of an outside of the respective head winding and inwardly urging TEG portions against the respective heading winding; or
(c) the one or more TEG portions comprise one or more lamination-powered TEG portions covering at least most of an exterior of the lamination stack, and a lamination-outer retainer runs around at least most of the exterior of the lamination stack and inwardly urges TEG portions against the lamination stack.

28. The electromechanical device of claim 27 wherein the stator comprises the head windings, and the one or more TEG portions comprise the one or more winding-powered TEG portions covering at least most of the head windings; and
the at least one respective heading winding of the head windings has the respective inner retainer running around at least most of an inside of the respective head winding and outwardly urging TEG portions against the respective heading winding.

29. The electromechanical device of claim 28 wherein the respective inner retainer is resiliently deformed inwards to outwardly urge TEG portions against the respective heading winding.

30. The electromechanical device of claim 29 wherein the at least one respective heading winding of the head windings has a respective outer retainer running around at least most of an outside of the respective head winding and inwardly urging TEG portions against the respective heading winding; and
the respective outer retainer is resiliently deformed outwards to inwardly urge TEG portions against the respective heading winding.

31. The electromechanical device of claim 30 wherein the one or more winding-powered TEG portions are biaxially flexible.

32. The electromechanical device of claim 28 wherein the one or more winding-powered TEG portions are biaxially flexible.

33. The electromechanical device of claim 28 wherein the one or more TEG portions cover at least 90% of head windings.

34. The electromechanical device of claim 28 wherein the at least one respective heading winding of the head windings has a respective outer retainer running around at least most of an outside of the respective head winding and inwardly urging TEG portions against the respective heading winding.

35. The electromechanical device of claim 27 wherein the stator comprises the head windings, and the one or more TEG portions comprise the one or more winding-powered TEG portions covering at least most of the head windings; and
the at least one respective heading winding of the head windings has a respective outer retainer running around at least most of an outside of the respective head winding and inwardly urging TEG portions against the respective heading winding.

36. The electromechanical device of claim 35 wherein the respective outer retainer is resiliently deformed outwards to inwardly urge TEG portions against the respective heading winding.

37. The electromechanical device of claim 35 wherein the one or more winding-powered TEG portions are biaxially flexible.

38. The electromechanical device of claim 27 wherein the one or more TEG portions comprise the one or more lamination-powered TEG portions covering at least most of the exterior of the lamination stack; and
an outer retainer runs around at least most of the exterior of the lamination stack and inwardly urges TEG portions against the lamination stack.

39. The electromechanical device of claim 38 wherein the lamination-outer retainer is resiliently deformed outwards to inwardly urge TEG portions against the lamination stack.

40. The electromechanical device of claim 27 comprising flow paths that convey fluid to cool the one or more winding-powered TEG portions in parallel to each other.

41. The electromechanical device of claim 27 comprising
flow paths arranged to convey fluid to cool the one or more winding-powered TEG portions; and
a cooling system that comprises a heat pump, supplies cooled fluid to the flow paths and cools an interior of a vehicle.

42. The electromechanical device of claim 27 wherein the one or more lamination-powered TEG portions cover at least 90% of the exterior of the lamination stack.

43. The electromechanical device of claim 27 wherein the one or more TEG portions comprise a rotor-powered TEG portion positioned on a portion of the rotor.

44. The electromechanical device of claim 43 wherein the rotor-powered TEG portion is on an interior of the rotor.

45. The electromechanical device of claim 27 comprising a casing encasing the stator, the rotor and the one or more the TEG portions.

46. A vehicle comprising:
an electromechanical device that at least one of (a) moves the vehicle or another vehicle or (b) regeneratively brakes the vehicle or the another vehicle;
wherein the electromechanical device comprises:
a stator;
a rotor; and
one or more thermoelectric generator (TEG) portions positioned to accept heat from at least one of the stator and the rotor;
the stator comprises a lamination stack; and
at least one of:
(a) the stator comprises head windings each comprising a respective ring about a respective end of the lamination stack,
the one or more TEG portions comprise one or more winding-powered TEG portions covering at least most of the head windings, and
the at least one respective heading winding of the head windings has a respective inner retainer running around at least most of an inside of the respective head winding and outwardly urging TEG portions against the respective heading winding;
(b) the stator comprises head windings each comprising a respective ring about a respective end of the lamination stack,
the one or more TEG portions comprise the one or more winding-powered TEG portions covering at least most of the head windings, and
the at least one respective heading winding of the head windings has a respective outer retainer running around at least most of an outside of the respective head winding and inwardly urging TEG portions against the respective heading winding; or
(c) the one or more TEG portions comprise one or more lamination-powered TEG portions covering at least most of an exterior of the lamination stack, and
a lamination-outer retainer runs around at least most of the exterior of the lamination stack and inwardly urges TEG portions against the lamination stack.
